(19) United States
(12) Patent Application Publication
(10) Pub. No.: US 2024/0241276 A1
(43) Pub. Date: Jul. 18, 2024

(54) METHOD AND SYSTEM FOR ROCK PHYSICS CONSTRAINED DATA INTEGRATION OF ELASTIC FWI PROPERTIES AND SEISMIC STACKS

(71) Applicant: ExxonMobil Technology and Engineering Company, Spring, TX (US)

(72) Inventors: Olivier M. BURTZ, Vesoul (FR); Di YANG, Spring, TX (US)

(21) Appl. No.: 18/559,131

(22) PCT Filed: May 6, 2022
(86) PCT No.: PCT/US2022/027988

§ 371 Date: Nov. 6, 2023

Related U.S. Application Data
(60) Provisional application No. 63/201,990, filed on May 21, 2021.

(51) Int. Cl. G01V 1/30; G01V 1/34; G06F 30/28

(52) U.S. Cl. CPC G01V 1/30; G01V 1/345; G06F 30/28; G01V 2210/66

(57) ABSTRACT

A computer-implemented method for integrating a full wavefield inversion (FWI) solution with a non-FWI solution. Computational costs for generating a large bandwidth FWI solution, such as to 50 Hz, may be considerable. However, limiting the FWI solution to a narrower frequency band, such as up to 20 Hz, renders the FWI solution less useful. To remedy this, an FWI solution that is band limited, such as up to 20 Hz, is integrated with a non-FWI solution. The non-FWI solution may comprise seismic stacks or non-seismic data, and is directed to a different frequency band, with at least part of the non-FWI solution frequency band being greater than 20 Hz. In this way, bandwidth extension may be performed for at least one subsurface physical property parameter by combining a band limited FWI solution with a non-FWI solution.

### CROSS-REFERENCE TO RELATED APPLICATION

This application claims priority to and the benefit of U.S. Provisional Application No. 63/201,990 having a filing date of May 21, 2021, the disclosure of which is incorporated herein by reference in its entirety.

### FIELD OF THE INVENTION

The present application relates generally to the field of hydrocarbon production. Specifically, the disclosure relates to a methodology for characterizing reservoirs by integrating full wavefield inversion (FWI) properties and seismic stacks.

### BACKGROUND OF THE INVENTION

This section is intended to introduce various aspects of the art, which may be associated with exemplary embodiments of the present disclosure. This discussion is believed to assist in providing a framework to facilitate a better understanding of particular aspects of the present disclosure. Accordingly, it should be understood that this section should be read in this light, and not necessarily as admissions of prior art.

Inferring petrophysical rock properties such as lithology (for example, relative amounts of shale and sand) and associated porosity may assist in a variety of tasks related to hydrocarbon production, such as characterizing subsurface rocks and hydrocarbon reservoirs, estimating hydrocarbon reserves, safely drilling wells, and developing models for how to best extract hydrocarbons. For example, hydrocarbons (e.g., oil or gas) are typically located in sand that is high porosity. In this regard, inferring spatial distribution of petrophysical properties may assist in appraising, developing, and producing a reservoir.

Petrophysical rock properties, such as the proportion of sand/shale and their porosity, may be measured from drilled wells or boreholes; however, such information is typically sparse due to the expense of drilling, logging, and coring these wells. Hence, well data alone may not suffice to infer spatially continuous petrophysical property estimates. Nevertheless, direct borehole measurements and/or subsequent core analysis from such wells provide ground truth measurements and may be used to understand rock property relations. Such relations as the ones between petrophysical properties and acoustic and elastic properties (compressional- and shear-wave velocities) may assist with inferring spatially variable petrophysical properties from geophysical data such as seismic. Separate from well data, seismic data may be obtained by sending sound waves through the subsurface and then recording the reflected waves that are returned, enabling the generation of an image of the subsurface called the seismic reflectivity.

Various relationships or mathematical models may relate petrophysical properties to seismic data. For example, one category of mathematical models is referred to as rock physics models (RPMs). RPMs most commonly relate petrophysical rock properties, such as porosity, volume of shale, and fluid (e.g., hydrocarbon or water) content to geophysical rock properties, such as compressional (or P-wave) and shear (or S-wave) velocities, and density. Geophysical rock properties may depend on elastic rock properties, such as bulk and shear moduli. RPMs, like other mathematical models, may be either inductive (or empirical) or deductive (or theoretical). Another category of mathematical models is referred to as angle-dependent amplitude models. The amplitudes of reflected seismic waves that have traveled through the subsurface may be related to changes in the geophysical properties of the rocks between one layer and the next, as well as the angle of incidence with which the wave impinged or reflected on the boundary. Consequently, changes in amplitude as a function of receiver offset (AVO) may be used to infer information about these elastic properties. To take advantage of this phenomenon, subsets of seismic reflection data corresponding to particular offsets (or angles) or small groups of offsets (or angles) may be processed into what are called angle stacks, with “offset” being the distance between a receiver and the seismic source.

Various approaches generate petrophysical properties from seismic angle stacks. In particular, seismic inversion, such as integrated technology like the integrated petrophysical inversion (iPi), delivers petrophysical properties of reservoirs by inverting amplitude versus offset information in the seismic angle stacks. See. e.g., Ratnanabha Sain et al., Integrated Petrophysical Inversion: A One-step Approach to Use Generalized Geophysical Data for Reservoir Characterization and Uncertainty Estimation, found at <http://seg.org/Annual-Meeting-2019/Education/Postconvention-Workshops>, W-7: Frontiers in Seismic Reservoir Characterization (2019). It also leverages rock physics and seismic velocities to complement the low frequency gap to produce an absolute band property. Like all seismic inversion, a successful iPi relies on seismic amplitude fidelity within a good range of reflection angles.

Another approach is ray-based seismic imaging technology, which may be inadequate in certain instances, such as complex geology. For example, unbalanced illumination in places like sub-salt reservoirs makes the lateral amplitude distribution unreliable for attribute computation. Conventional incident angle definition is also difficult due to the irregular ray path in complex structures with high velocity contrasts. Therefore, seismic inversion with such data produces compromised property estimation.

Other approaches include wave-based methods, such as least square reverse time migration (LS-RTM) and full waveform inversion, are capable of properly handling the issues above by utilizing advanced physics in simulation. However, the benefit comes with a computational cost that exponentially increases with frequency. The ambiguous angle definition problem also exists for LS-RTM, which limits the accuracy of LS-RTM angle stacks.

Other background references may include U.S. Pat. Nos. 9,081,115, 10,816,687, and 10,838,092 and U.S. Patent Application Publication Nos. 2010/0186950, 2017/0097428, 2020/0041692, and 2020/0132873.

### SUMMARY OF THE INVENTION

In one or some embodiments, a computer-implemented method for integrating a full wavefield inversion (FWI) solution with a non-FWI solution is disclosed. The method includes: accessing the FWI solution, the FWI solution over a limited FWI bandwidth and comprising one or more FWI properties generated using FWI; accessing a non-FWI solution, the non-FWI solution over a non-FWI bandwidth that extends beyond the limited FWI bandwidth; combining the FWI solution with the non-FWI solution in order to generate a model estimate of at least a part of a subsurface, the model estimate extending beyond the limited FWI bandwidth; comparing the model estimate with one or more statistical or rock physics based models of the subsurface; modifying the model estimate, based on the comparison of the model estimate with one or more statistical models or rock physics based models of the subsurface, in order to generate an updated model estimate; iterating with the updated model estimate and the one or more statistical models or rock physics based models of the subsurface in order to further refine the updated model estimate; and using the updated model estimate for hydrocarbon management.

### BRIEF DESCRIPTION OF THE DRAWINGS

The present application is further described in the detailed description which follows, in reference to the noted plurality of drawings by way of non-limiting examples of exemplary implementations, in which like reference numerals represent similar parts throughout the several views of the drawings. In this regard, the appended drawings illustrate only exemplary implementations and are therefore not to be considered limiting of scope, for the disclosure may admit to other equally effective embodiments and applications.

FIG. 1 illustrates a block diagram of an example statistical inference framework.

FIG. 2 illustrates a first example workflow in which an FWI solution with a non-FWI solution are combined in order to generate a model estimate.

FIG. 3 illustrates a second example workflow for generating a model estimate using a methodology of blending an FWI solution with a non-FWI solution.

FIGS. 4A to 4H are graphs of various metrics versus time for a 1-dimensional (1-D or 1D) inversion example at a well location, including FIGS. 4A to 4C illustrating graphs of model parameters Vp versus time (FIG. 4A), Vp/Vs ratio versus time (FIG. 4B), and Acoustic Impedance (AI) versus time (FIG. 4C), with a first curve illustrating the estimated model parameter, a second curve indicative of the true model of full band, and a third curve indicative of prior models build from the classification. FIG. 4D is a graph of the Least-Squares Reverse Time Migration (LSRTM) versus time. FIG. 4E is a graph of the elastic FWI generated impedance (Ip) versus time. FIG. 4F is a graph of Vp/Vs ratio versus time. FIG. 4G is a graph of Vp versus time, with one curve comprising synthetic data and another curve comprising input data. FIG. 4H is a graph of facies showing the rock types that the classifier assigned at each data point.

FIGS. 5A to 5C are probability distribution functions for each rock type in 3 dimensions, including FIG. 5A a graph of AI versus Vp/Vs, FIG. 5B a graph of Vp versus Vp/Vs, and FIG. 5C a graph of AI versus Vp.

FIGS. 6A to 6F are example 2-dimensional (2-D to 2D) sectional views, with FIG. 6A illustrating Vp using the disclosed methodology (with Vp Blended indicating a mixture or blending of an FWI solution (such as an elastic FWI solution) and a non-FWI solution), with FIG. 6B illustrating Vp/Vs using the disclosed methodology (with Vp/Vs Blended indicating a mixture or blending of an FWI solution and a non-FWI solution), and with FIG. 6C illustrating impedance Ip using the disclosed methodology (with Ip Blended indicating a mixture or blending of an FWI solution and a non-FWI solution). In comparison, FIGS. 6D to 6F are images of various subsurface physical property parameters using band-limited elastic FWI, with FIGS. 6D to 6F illustrating Vp, Vp/Vs, and impedance Ip, respectively, using band-limited elastic FWI

FIG. 7 is a diagram of an exemplary computer system that may be utilized to implement the methods described herein.

### DETAILED DESCRIPTION OF THE INVENTION

The methods, devices, systems, and other features discussed below may be embodied in a number of different forms. Not all of the depicted components may be required, however, and some implementations may include additional, different, or fewer components from those expressly described in this disclosure. Variations in the arrangement and type of the components may be made without departing from the spirit or scope of the claims as set forth herein. Further, variations in the processes described, including the addition, deletion, or rearranging and order of logical operations, may be made without departing from the spirit or scope of the claims as set forth herein.

It is to be understood that the present disclosure is not limited to particular devices or methods, which may, of course, vary. It is also to be understood that the terminology used herein is for the purpose of describing particular embodiments only, and is not intended to be limiting. As used herein, the singular forms “a,” “an,” and “the” include singular and plural referents unless the content clearly dictates otherwise. Furthermore, the words “can” and “may” are used throughout this application in a permissive sense (i.e., having the potential to, being able to), not in a mandatory sense (i.e., must). The term “include,” and derivations thereof, mean “including, but not limited to.” The term “coupled” means directly or indirectly connected. The word “exemplary” is used herein to mean “serving as an example, instance, or illustration.” Any aspect described herein as “exemplary” is not necessarily to be construed as preferred or advantageous over other aspects. The term “uniform” means substantially equal for each sub-element, within about plus or minus (±) 10% variation.

The term “seismic data” as used herein broadly means any data received and/or recorded as part of the seismic surveying and interpretation process, including displacement, velocity and/or acceleration, pressure and/or rotation, wave reflection, and/or refraction data. “Seismic data” is also intended to include any data (e.g., seismic image, migration image, reverse-time migration image, pre-stack image, partially-stack image, full-stack image, post-stack image or seismic attribute image) or interpretation quantities, including geophysical properties such as one or more of: elastic properties (e.g., P and/or S wave velocity, P-Impedance, S-Impedance, density, attenuation, anisotropy and the like); and porosity, permeability or the like, that the ordinarily skilled artisan at the time of this disclosure will recognize may be inferred or otherwise derived from such data received and/or recorded as part of the seismic surveying and interpretation process. Thus, this disclosure may at times refer to “seismic data and/or data derived therefrom,” or equivalently simply to “seismic data.” Both terms are intended to include both measured/recorded seismic data and such derived data, unless the context clearly indicates that only one or the other is intended. “Seismic data” may also include data derived from traditional seismic (e.g., acoustic) data sets in conjunction with other geophysical data, including, for example, gravity plus seismic; gravity plus electromagnetic plus seismic data, etc. For example, joint-inversion utilizes multiple geophysical data types.

The term “geophysical data” as used herein broadly includes seismic data, as well as other data obtained from non-seismic geophysical methods such as electrical resistivity. In this regard, examples of geophysical data include, but are not limited to, seismic data, gravity surveys, magnetic data, electromagnetic data, well logs, image logs, radar data, or temperature data.

The term “geological features” (interchangeably termed geo-features) as used herein broadly includes attributes associated with a subsurface, such as any one, any combination, or all of: subsurface geological structures (e.g., channels, volcanos, salt bodies, geological bodies, geological layers, etc.); boundaries between subsurface geological structures (e.g., a boundary between geological layers or formations, etc.); or structure details about a subsurface formation (e.g., subsurface horizons, subsurface faults, mineral deposits, bright spots, salt welds, distributions or proportions of geological features (e.g., lithotype proportions, facies relationships, distribution of petrophysical properties within a defined depositional facies), etc.). In this regard, geological features may include one or more subsurface features, such as subsurface fluid features, that may be hydrocarbon indicators (e.g., Direct Hydrocarbon Indicator (DHI)). Examples of geological features include, without limitation salt, fault, channel, environment of deposition (EoD), facies, carbonate, rock types (e.g., sand and shale), horizon, stratigraphy, or geological time, and are disclosed in U.S. Patent Application Publication No. 2010/0186950 A1, incorporated by reference herein in its entirety.

The terms “velocity model,” “density model.” “physical property model,” or other similar terms as used herein refer to a numerical representation of parameters for subsurface regions. Generally, the numerical representation includes an array of numbers, typically a 2-D or three dimensional (3-D) array, where each number, which may be called a “model parameter,” is a value of velocity, density, or another physical property in a cell, where a subsurface region has been conceptually divided into discrete cells for computational purposes. For example, the spatial distribution of velocity may be modeled using constant-velocity units (layers) through which ray paths obeying Snell's law can be traced. A 3-D geologic model (particularly a model represented in image form) may be represented in volume elements (voxels), in a similar way that a photograph (or 2-D geologic model) is represented by picture elements (pixels). Such numerical representations may be shape-based or functional forms in addition to, or in lieu of, cell-based numerical representations.

The term “subsurface model” as used herein refer to a numerical, spatial representation of a specified region or properties in the subsurface.

The term “geologic model” as used herein refer to a subsurface model that is aligned with specified geological feature such as faults and specified horizons.

The term “reservoir model” as used herein refer to a geologic model where a plurality of locations have assigned properties including any one, any combination, or all of rock type, EoD, subtypes of EoD (sub-EoD), porosity, clay volume, permeability, fluid saturations, etc.

For the purpose of the present disclosure, subsurface model, geologic model, and reservoir model are used interchangeably unless denoted otherwise.

Stratigraphic model is a spatial representation of the sequences of sediment, formations and rocks (rock types) in the subsurface. Stratigraphic model may also describe the depositional time or age of formations.

Structural model or framework results from structural analysis of reservoir or geobody based on the interpretation of 2D or 3D seismic images. For examples, the reservoir framework comprises horizons, faults and surfaces inferred from seismic at a reservoir section.

As used herein, “hydrocarbon management” or “managing hydrocarbons” includes any one, any combination, or all of the following: hydrocarbon extraction; hydrocarbon production, (e.g., drilling a well and prospecting for, and/or producing, hydrocarbons using the well; and/or, causing a well to be drilled, e.g., to prospect for hydrocarbons); hydrocarbon exploration; identifying potential hydrocarbon-bearing formations; characterizing hydrocarbon-bearing formations; identifying well locations; determining well injection rates; determining well extraction rates; identifying reservoir connectivity; acquiring, disposing of, and/or abandoning hydrocarbon resources; reviewing prior hydrocarbon management decisions; and any other hydrocarbon-related acts or activities, such activities typically taking place with respect to a subsurface formation. The aforementioned broadly include not only the acts themselves (e.g., extraction, production, drilling a well, etc.), but also or instead the direction and/or causation of such acts (e.g., causing hydrocarbons to be extracted, causing hydrocarbons to be produced, causing a well to be drilled, causing the prospecting of hydrocarbons, etc.). Hydrocarbon management may include reservoir surveillance and/or geophysical optimization. For example, reservoir surveillance data may include, well production rates (how much water, oil, or gas is extracted over time), well injection rates (how much water or CO₂ is injected over time), well pressure history, and time-lapse geophysical data. As another example, geophysical optimization may include a variety of methods geared to find an optimum model (and/or a series of models which orbit the optimum model) that is consistent with observed/measured geophysical data and geologic experience, process, and/or observation.

As used herein, “obtaining” data generally refers to any method or combination of methods of acquiring, collecting, or accessing data, including, for example, directly measuring or sensing a physical property, receiving transmitted data, selecting data from a group of physical sensors, identifying data in a data record, and retrieving data from one or more data libraries.

As used herein, terms such as “continual” and “continuous” generally refer to processes which occur repeatedly over time independent of an external trigger to instigate subsequent repetitions. In some instances, continual processes may repeat in real time, having minimal periods of inactivity between repetitions. In some instances, periods of inactivity may be inherent in the continual process.

If there is any conflict in the usages of a word or term in this specification and one or more patent or other documents that may be incorporated herein by reference, the definitions that are consistent with this specification should be adopted for the purposes of understanding this disclosure.

As discussed in the background, various solutions are available to generate an earth model. One such solution comprises inversion, such as full wavefield inversion (FWI), of seismic data as a way in which to infer subsurface physical property parameters. Example subsurface physical property parameters include any one, any combination, or all of: compressional wave velocity (Vₚ), shear wave velocity (Vₛ), density (ρ), anisotropic parameters (e.g., near-offset effects (δ), long-offset effects (ε), and S-wave effects (γ)); and attenuation of the medium. Other subsurface physical property parameters in addition to or instead of the listed parameters are contemplated. The various subsurface physical property parameters may be manifested in a model, such as a rock model, with the model being parameterized with one or more of the subsurface physical property parameters (e.g., individual subsurface physical property parameters and/or combinations of subsurface physical property parameters, such as Vₚ/Vₛ or acoustic impedance).

One type of FWI comprises elastic FWI, which is configured to directly translate the amplitude variation information into elastic properties without explicitly defining reflection angles. An example of anisotropic elastic FWI is disclosed in U.S. Patent Application Publication No. 2020/0132873 A1, incorporated by reference herein in its entirety. However, the computation cost of elastic FWI is considerable. As a result, practical elastic FWI on a real-world scale problem is limited in frequency content. In particular, elastic FWI may be configured to generate a limited-band solution (e.g., a narrow-band solution less than 20 Hertz (Hz)) with a lower computation cost. However, failing to account for higher frequencies, such as frequencies greater than 20 Hz (e.g., frequencies up to 50 Hz), renders the band-limited elastic FWI solution as less useful. In this regard, bandwidth extension may be performed for at least one subsurface physical property parameter by combining multiple solutions (e.g., bandwidth extension upward by combining an elastic FWI solution with a non-FWI solution; bandwidth extension downward by combining a non-FWI solution with an FWI solution).

Thus, in one or some embodiments, a model configured to characterize at least a part of the subsurface is generated by integrating an FWI solution, such as an elastic FWI solution, with one or more non-FWI solutions. The model may comprise a rock physics model that is indicative of one or more rock properties of the subsurface. In particular, multiple bandwidth geophysical data/products may be indicative of one or more properties of the subsurface, such as one or more rock properties. In turn, the model may be generated using at least two, any combination, or all of the following solutions that are indicative of rock property(ies); FWI (such as elastic FWI), seismic data (e.g., seismic stacks); and non-seismic data (e.g., gravity, electro-magnetic), where FWI may be in generality any one or any combination of acoustic physics (see, for example, U.S. Pat. No. 9,081,115, incorporated by reference herein in its entirety), elastic physics (see, for example, U.S. Patent Application Publication No. 2020/0132873 A1, incorporated by reference herein in its entirety), anisotropic physics (see, for example, U.S. Pat. No. 10,838,092, incorporated by reference herein in its entirety), viscous physics (see, for example, U.S. Patent Application Publication No. 2017/0097428 A1, incorporated by reference herein in its entirety), and poro-elastic physics (or its combinations thereof), with a non-FWI solution that may be any combination of rock physics based prior, statistically driven prior on rock properties, ray based and wave-based imaged products such as offset and angle stacks. In a first specific embodiment, the geophysical data/products that are integrated to form the model, such as the rock physics model, include bandwidths that are mutually exclusive. In a second specific embodiment, at least two of the geophysical data/products that are integrated to form the model have bandwidths that are not coextensive, but may overlap.

As one example, elastic FWI may generate a solution for a narrower frequency band (e.g., 20 Hz and below) with less computational cost than a solution over a wider frequency band (e.g., up to 50 Hz). In this regard, the elastic FWI solution for the narrower frequency band may be integrated with one or both of a seismic data-based solution (such as seismic stacks, seismic velocities, etc.) or a non-seismic data-based solution (such as gravimetry or electromagnetism data) with a bandwidth that is higher or lower than the narrower frequency band of the elastic FWI solution. In the instance of seismic stacks, it may be difficult to obtain a solution for lower frequencies (e.g., 0 Hz to 5 Hz) but may be generated for higher frequencies (e.g., 5 Hz to 50 Hz). Thus, the elastic FWI solution and the seismic stacking solution, with mutually exclusive bandwidths (e.g., elastic FWI solution from 0 Hz to 20 Hz and the seismic stacking solution from 20 Hz to 50 Hz) may be integrated to generate the model, such as the rock physics model. Alternatively, the elastic FWI solution and the seismic stacking solution, with overlapping but not coextensive bandwidths (e.g., elastic FWI solution from 0 Hz to 20 Hz and the seismic stacking solution from 5 Hz to 50 Hz) may be integrated to generate the model, such as the rock physics model.

Various ways are contemplated to integrate the multiple bandwidth geophysical data/products (indicative of the rock property(ies)) using an integration framework and thereby expanding the limited bandwidth of the elastic FWI In one or some embodiments, the integration of the multiple bandwidth geophysical data/products may be viewed as solving an inverse problem. In particular, a model, such as a rock model, may initially be selected based on actual data (e.g., well log data associated with the actual subsurface). Thereafter, forward modeling may be used for a likelihood function to measure the goodness of fit of the model against one or more sources of information (e.g., one or both of: (i) the rock property(ies) generated by elastic FWI, seismic solutions and/or non-seismic solutions; and (ii) general understanding or assumptions about the subsurface, which may be based on non-seismic information, such as well information). In turn, using the likelihood function, the model may be iteratively modified until the likelihood function indicates that the output of the model and the sources of information are within tolerance (e.g., backpropagating the residual into the model perturbation may be performed iteratively until the difference in the data generated by the model and the actual data is within tolerance).

In one or some embodiments, the integration methodology comprises solving a maximum a posterior (MAP) problem. Alternatively, the integration methodology may comprise a Bayesian framework. Still, other solutions for the inverse problem are contemplated. In either integration methodology, the model (indicative of the rock property(ies)) may be solved simultaneously across the multiple bands such that the solution is not performed in a piecemeal fashion. After generating the model, such as the rock model, the model may be used for hydrocarbon management, such as described above.

Thus, the various inputs, such as the elastic FWI solution, the seismic solution, and the non-seismic solution, may be input to the integration framework. In one or some embodiments, the various inputs may be weighted, such as weighted differently, based on reliability (e.g., trustworthiness of the data). Alternatively, the various inputs are not weighted. In this way, the bandwidth of an FWI-based solution, intentionally band limited to reduce computational requirements, may be extended by integration with other non-FWI-based solutions.

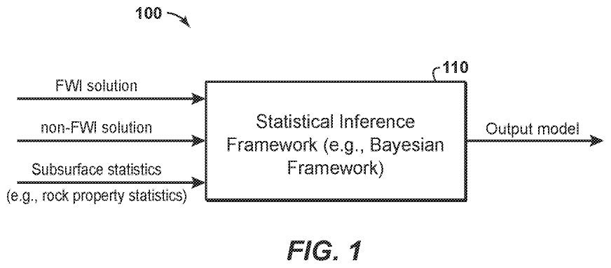

Referring to the figures. FIG. 1 illustrates a block diagram 100 of an example statistical inference framework 110. The statistical inference framework 110 may comprise one or more types of frameworks, such as a Bayesian Framework. Other frameworks are contemplated. The statistical inference framework 110 may receive as input a FWI solution (such as an elastic FWI solution), one or more non-FWI solutions (e.g., seismic data solution and/or non-seismic data solution), and subsurface statistics (e.g., rock property statistics). As discussed above, the FWI solution may be of a limited bandwidth (e.g., up to 20 Hz) whereas the one or more non-FWI solutions may include bandwidth that is outside of the limited bandwidth of the FWI solution. As one example, the one or more non-FWI solutions, such as seismic stack solution, may be directed to a bandwidth (e.g., 5 Hz to 50 Hz) outside of the limited bandwidth of the elastic FWI solution (e.g., less than 20 Hz). In this way, the bandwidth of one or more non-FWI solutions input to the statistical inference framework 110 may at least partly overlap with the bandwidth of the FWI solution. Alternatively, the bandwidth of one or more non-FWI solutions and the FWI solution are mutually exclusive to one another.

In practice, the statistical inference framework 110 may iteratively modify a model, such as a rock model, which may initially be selected based on actual data (such as well log data). Specifically, the statistical inference engine 110 may iteratively modify the model in order to determine fitness to the subsurface statistics. Responsive to determining fitness of the model within tolerance, the statistical inference engine 110 may output the model.

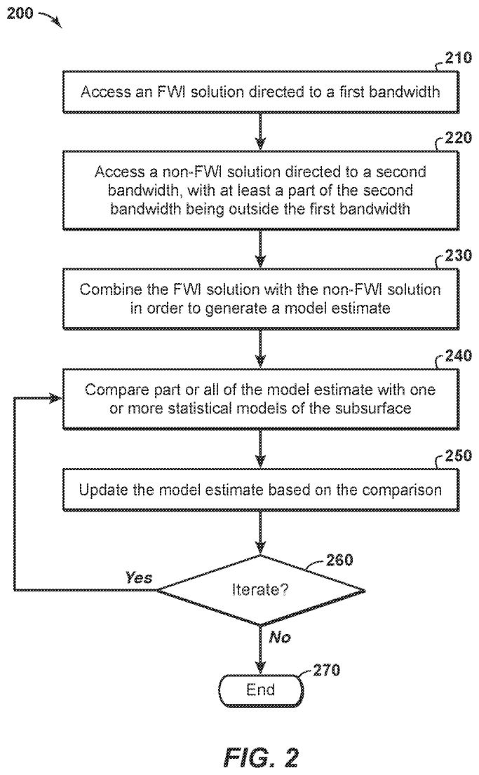

FIG. 2 illustrates a first example workflow 200 in which an FWI solution with a non-FWI solution are combined in order to generate a model estimate. At block 210, an FWI solution (such as an elastic FWI solution) directed to a first bandwidth (such as a limited bandwidth less than 20 Hz) is accessed. At block 220, one or more non-FWI solutions are accessed, with the one or more non-FWI solutions directed to a second bandwidth that is at least partly outside the first bandwidth (e.g., either partly or entirely outside the first bandwidth). At block 230, the FWI solution and the one or more non-FWI solutions are combined to generate the model estimate. At block 240, part or all of the model estimate are compared with one or more statistical models of the subsurface. At block 250, the model estimate is updated based on the comparison. At block 260, it is determined whether to iterate (e.g., based on the likelihood function to measure the goodness of fit of the model against one or more sources of information). If so, workflow 200 loops back to block 240. If not, workflow 200 progresses to end in block 270.

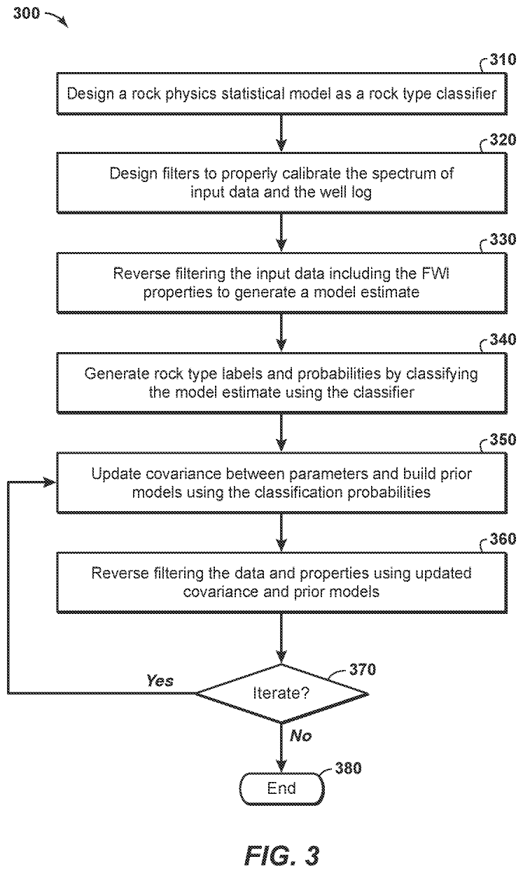

FIG. 3 illustrates a second example workflow 300 for generating a model estimate using a methodology of blending an FWI solution with a non-FWI solution. At block 310, a rock physics statistical model as a rock type classifier is designed. For example, an initial selection of the rock physics statistical model may be based on one or more inputs. In the instance where measured data is available for the present area (e.g., well information in the present area), a rock physics statistical model may be selected to comport with the available data (e.g., selecting a specific rock physics statistical model from a plurality of available rock physics statistical model based on the available data). Alternatively, a rock physics statistical model may be selected in the instance where measured data is unavailable for the present area (e.g., measurements have not been taken since no well has been drilled in the prospect; however, well data in an adjacent area is available to select a rock physics statistical model). Thus, the selected rock physics statistical model may comport with the expectations of the available data. In a particular example, in the event that the area is a carbonate field and pure carbonate with clean calcite is expected, then the rock physics statistical model may be selected accordingly (e.g., the range of the velocity for the model comports with a carbonate field having pure carbonate with clean calcite).

At block 320, filters are designed to properly calibrate the spectrum of input data and the well log. For example, filters may be selected for use in calibrating data (e.g., input data and the well log) which may be used for a forward modeling operation, thereby constraining the solution from one iteration to the next. At block 330, reverse filtering of the input data, including the FWI properties, is performed in order to generate a model estimate. For example, in inverse forward modeling (e.g., reverse filtering or inverse modeling), the goal is to generate a model estimate. As such, block 330 may be used to perform this step.

At block 340, rock type labels and probabilities by classifying the model estimate using the classifier are generated. Thus, block 340 may be used as a check against a general understanding or assumption as to the rock statistics.

At block 350, covariance between parameters and build prior models are updated using the classification probabilities. As one example, the classification probabilities may comprise one or more potential rock types (e.g., machine learning may be used to select the probable rock type). The potential rock types, in turn, may have associated properties (e.g., particular shapes for various parameters). In particular, the potential rock type may have an associated shape, providing an indication of how different parameters may correlate with one another. For example, an initial selection of the rock type (which may be a random guess or may be based on the data available), with its associated properties, may be used in order to try to fit the data. The system may iterate selecting different rock types (or different combinations of rock types), with associated properties, in order to fit the data. In this way, the classification probabilities may be leveraged rock in order, for example, to leverage blending of the high frequency information with the low frequency information.

At block 360, reverse filtering of the data and properties are performed using updated covariance and prior models. Thus, in one or some embodiments, 360 is similar to 330. At block 370, it is determined whether to continue iterating. If so, workflow 300 loops back to block 350. If not, workflow 300 ends at block 380. In this regard, block 370 may determine whether to continue iterating based on one or more convergence criteria (e.g., set a number of iterations; set a predetermined error fit; etc.)

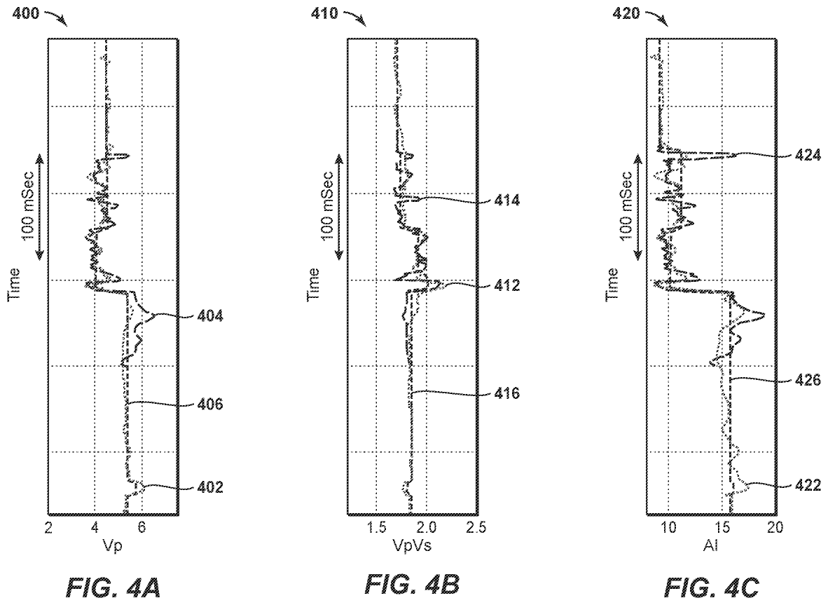

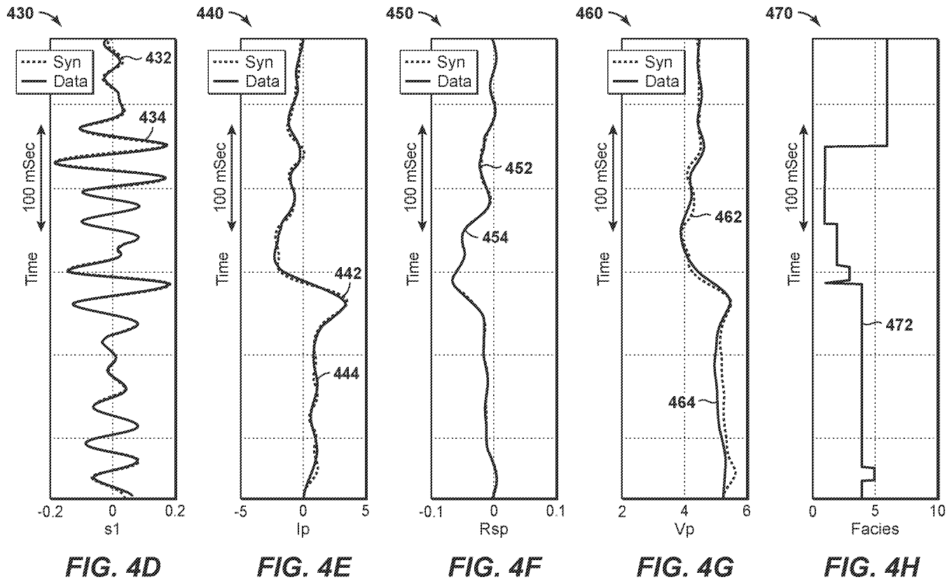

FIGS. 4A to 4H are graphs of various metrics versus time for a 1-dimensional (1-D or ID) inversion example at a well location, including FIGS. 4A to 4C illustrating graphs of various model parameters. For example, FIG. 4A illustrates a graph 400 of Vp versus time in 100 milliseconds blocks (100 mSec), with curve 402 illustrating the estimated Vp, curve 404 indicative of the true model of full band, and curve 406 indicative of prior models built from the classification. FIG. 4B illustrates a graph 410 of Vp/Vs versus time in 100 mSec, with curve 412 illustrating the estimated Vp/Vs ratio, curve 414 indicative of the true model of full band, and curve 416 indicative of prior models built from the classification. FIG. 4C illustrates a graph 420 of Acoustic Impedance (AI) versus time in 100 mSec, with curve 422 illustrating the estimated AI, curve 424 indicative of the true model of full band, and curve 426 indicative of prior models built from the classification.

FIG. 4D is a graph 430 of the Least-Squares Reverse Time Migration (LSRTM), indicated as s1, versus time in 100 mSec, with curve 432 comprising synthetic data and curve 434 comprising input data. FIG. 4E is a graph 440 of the elastic FWI generated impedance (Ip) versus time in 100 mSec, with curve 442 comprising synthetic data and curve 444 comprising input data. FIG. 4F is a graph 450 of Vp/Vs ratio versus time in 100 mSec, with curve 452 comprising synthetic data and curve 454 comprising input data. FIG. 4G is a graph 460 of Vp versus time in 100 mSec, with curve 462 comprising synthetic data and curve 464 comprising input data. FIG. 4H is a graph 470 of facies versus time in 100 mSec with curve 472 showing the rock types that the classifier assigned at each data point.

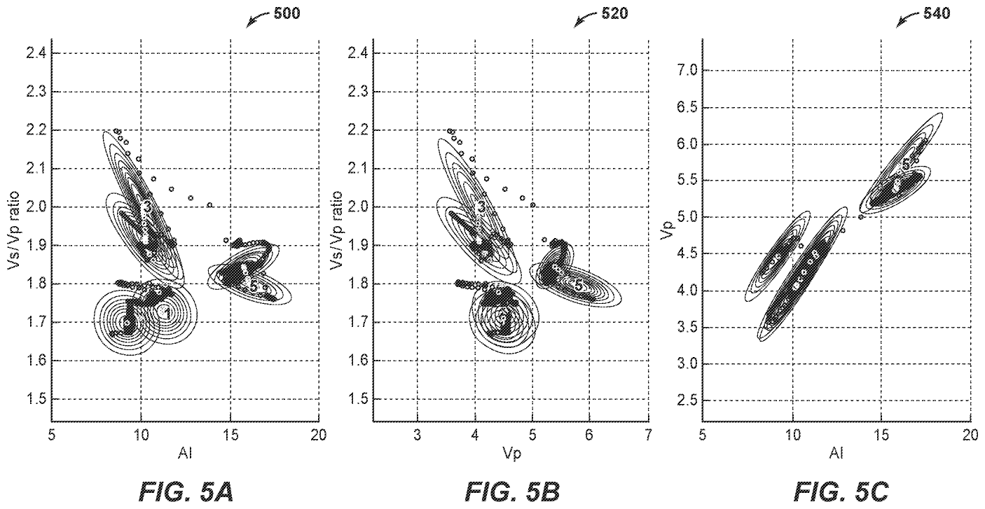

FIGS. 5A to 5C are probability distribution functions for each rock type in 3 dimensions, including FIG. 5A of a graph 500 of AI (which is velocity times density (e.g., kilometers per second (km/s)*grams per cubic centimeter (g/cm³)) versus Vp/Vs ratio (shown as Vp/Vs ratio on axis), FIG. 5B of a graph 520 of Vp versus Vp/Vs ratio (shown as Vp/Vs ratio on axis), and FIG. 5C of a graph 540 of AI versus Vp, which is kilometers per second (km/s). As discussed above, various properties associated with rock types may be used in an attempt to fit the data. FIGS. 5A to 5C provide examples of such in which different rock types (and associated properties) are illustrated, with such examples being used in an attempt to fit the data. Further, the different rock types may be iteratively analyzed in order to obtain the best fit to the data. The a priori information of FIGS. 5A to 5C may help combining the high frequency dataset of FIG. 4D (curve 434) with the lower frequency datasets of FIGS. 4E to 4G (curves 444, 454, and 464) to produce the full-bandwidth results displayed in FIGS. 4A to 4C (curves 402, 412, and 422). Those estimates may be very close to the actual properties measured in the well (curves 404, 414, and 424). Forward modeling of the results (curves 432, 442, 452, and 462) may be very close to the input data (curves 434, 444, 454, and 464) indicating that the available data has been fairly well explained. Additionally, a log of rock types (FIG. 4H, curve 472) may be produced that comports with the estimated properties. Those facies may be defined in FIGS. 5A to 5C.

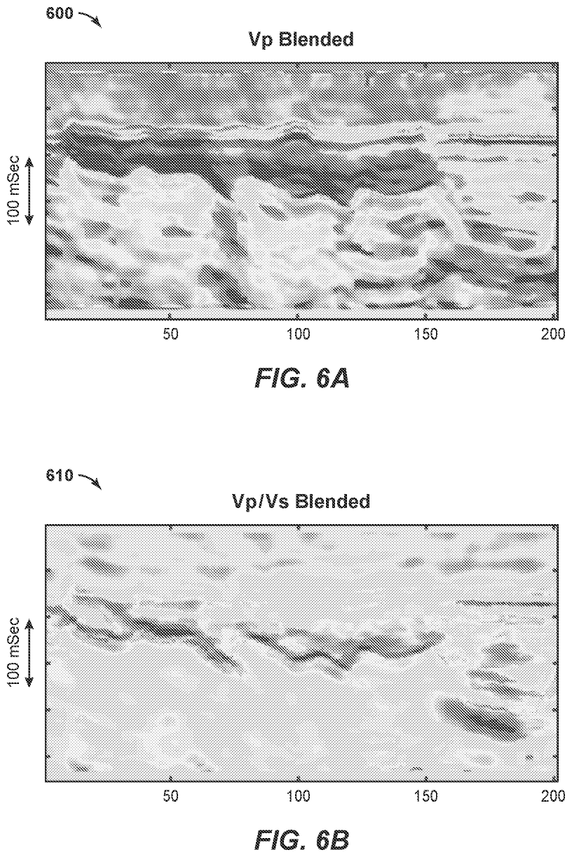

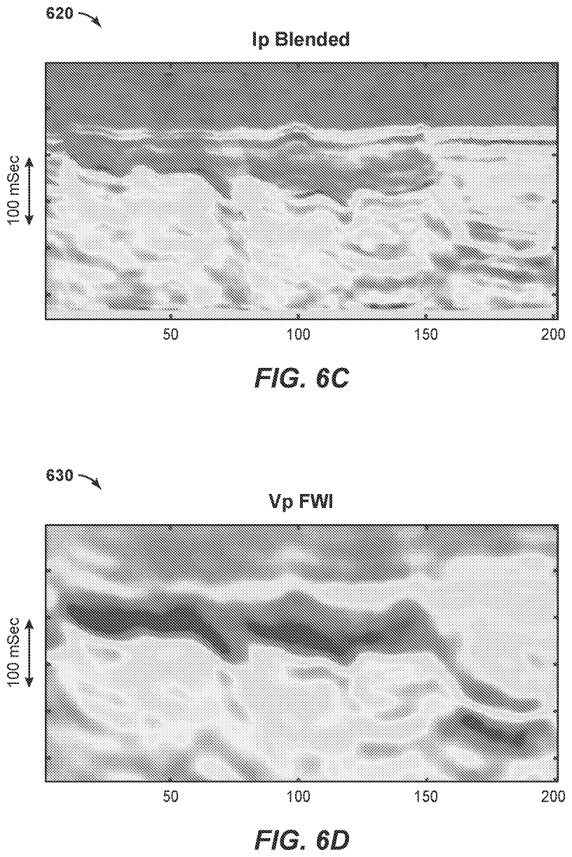

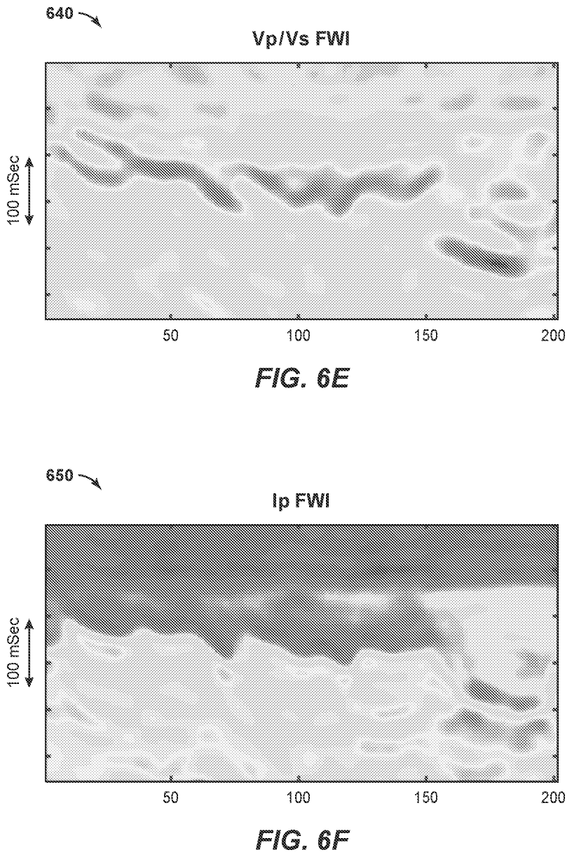

FIGS. 6A to 6F are example 2-dimensional (2-D to 2D) sectional views 600, 610, 620, 630, 640, and 650. The vertical scale is time, horizontal scale is space (labeled by trace number, which there are 50 meters (m) between each trace). Color intensity is the magnitude of property (e.g., in sectional view 630, black is high Vp, while white is low Vp). For the 2D sectional views 600, 610, 620, 630, 640, 650, FIG. 6A illustrating the sectional view 610 of estimated Vp using the disclosed methodology (with Vp Blended indicating a mixture or blending of an FWI solution (such as an elastic FWI solution) and a non-FWI solution) versus time in 100 mSec, while FIG. 6B illustrates the sectional view 620 of Vp/Vs using the disclosed methodology (with Vp/Vs Blended indicating a mixture or blending of an FWI solution and a non-FWI solution) versus time in 100 mSec, and FIG. 6C illustrates the sectional view 630 of impedance Ip using the disclosed methodology (with Ip Blended indicating a mixture or blending of an FWI solution and a non-FWI solution). In comparison, FIGS. 6D to 6F are sectional views 630, 640 and 650 (e.g., images) of various subsurface physical property parameters using band-limited elastic FWI (e.g., low-frequency, such as 20 Hz and less) versus time in 100 mSec, with FIGS. 6D to 6F illustrating Vp, Vp/Vs, and impedance Ip, respectively, using band-limited elastic FWI. Comparing FIGS. 6A and 6D, FIGS. 6E and 6E, and FIGS. 6C and 6F, it is shown that the blended solution, in which a band-limited FWI solution (such as an elastic FWI solution) combined or blended with a non-FWI solution (such as a non-elastic FWI solution) of limited bandwidth, significantly improves over solely using the band-limited FWI solution.

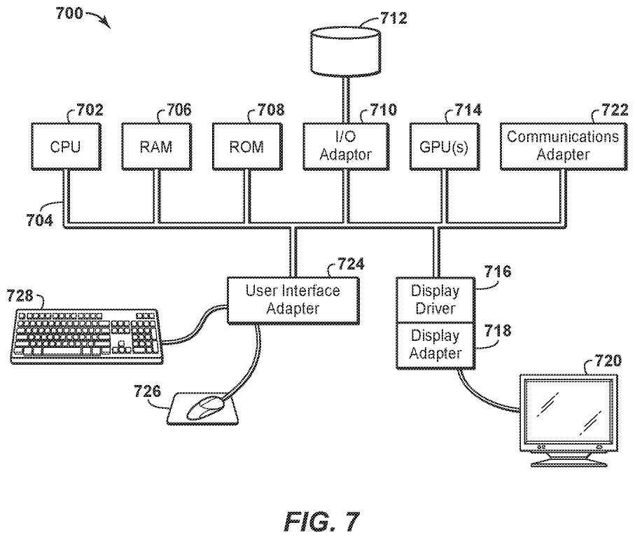

In all practical applications, the present technological advancement is used in conjunction with a computer, programmed in accordance with the disclosures herein. For example, FIG. 7 is a diagram of an exemplary computer system 700 that may be utilized to implement methods described herein. A central processing unit (CPU) 702 is coupled to system bus 704. The CPU 702 may be any general-purpose CPU, although other types of architectures of CPU 702 (or other components of exemplary computer system 700) may be used as long as CPU 702 (and other components of computer system 700) supports the operations as described herein. Those of ordinary skill in the art will appreciate that, while only a single CPU 702 is shown in FIG. 7, additional CPUs may be present. Moreover, the computer system 700 may comprise a networked, multi-processor computer system that may include a hybrid parallel CPU/GPU system. The CPU 702 may execute the various logical instructions according to various teachings disclosed herein. For example, the CPU 702 may execute machine-level instructions for performing processing according to the operational flow described.

The computer system 700 may also include computer components such as non-transitory, computer-readable media. Examples of computer-readable media include computer-readable non-transitory storage media, such as a random access memory (RAM) 706, which may be SRAM, DRAM, SDRAM, or the like. The computer system 700 may also include additional non-transitory, computer-readable storage media such as a read-only memory (ROM) 708, which may be PROM, EPROM, EEPROM, or the like. RAM 706 and ROM 708 hold user and system data and programs, as is known in the art. The computer system 700 may also include an input/output (I/O) adapter 710, a graphics processing unit (GPU) 714, a communications adapter 722, a user interface adapter 724, a display driver 716, and a display adapter 718.

The I/O adapter 710 may connect additional non-transitory, computer-readable media such as storage device(s) 712, including, for example, a hard drive, a compact disc (CD) drive, a floppy disk drive, a tape drive, and the like to computer system 700. The storage device(s) may be used when RAM 706 is insufficient for the memory requirements associated with storing data for operations of the present techniques. The data storage of the computer system 700 may be used for storing information and/or other data used or generated as disclosed herein. For example, storage device(s) 712 may be used to store configuration information or additional plug-ins in accordance with the present techniques. Further, user interface adapter 724 couples user input devices, such as a keyboard 728, a pointing device 726 and/or output devices to the computer system 700. The display adapter 718 is driven by the CPU 702 to control the display on a display device 720 to, for example, present information to the user such as subsurface images generated according to methods described herein.

The architecture of computer system 700 may be varied as desired. For example, any suitable processor-based device may be used, including without limitation personal computers, laptop computers, computer workstations, and multi-processor servers. Moreover, the present technological advancement may be implemented on application specific integrated circuits (ASICs) or very large scale integrated (VLSI) circuits. In fact, persons of ordinary skill in the art may use any number of suitable hardware structures capable of executing logical operations according to the present technological advancement. The term “processing circuit” encompasses a hardware processor (such as those found in the hardware devices noted above). ASICs. and VLSI circuits. Input data to the computer system 700 may include various plug-ins and library files. Input data may additionally include configuration information.

Preferably, the computer is a high-performance computer (HPC), known to those skilled in the art. Such high-performance computers typically involve clusters of nodes, each node having multiple CPU's and computer memory that allow parallel computation. The models may be visualized and edited using any interactive visualization programs and associated hardware, such as monitors and projectors. The architecture of system may vary and may be composed of any number of suitable hardware structures capable of executing logical operations and displaying the output according to the present technological advancement. Those of ordinary skill in the art are aware of suitable supercomputers available from Cray or IBM or other cloud computing based vendors such as Microsoft, Amazon.

The above-described techniques, and/or systems implementing such techniques, can further include hydrocarbon management based at least in part upon the above techniques, including using the one or more generated geological models in one or more aspects of hydrocarbon management. For instance, methods according to various embodiments may include managing hydrocarbons based at least in part upon the one or more generated geological models and data representations (e.g., seismic images, feature probability maps, feature objects, etc.) constructed according to the above-described methods. In particular, such methods may include drilling a well, and/or causing a well to be drilled, based at least in part upon the one or more generated geological models and data representations discussed herein (e.g., such that the well is located based at least in part upon a location determined from the models and/or data representations, which location may optionally be informed by other inputs, data, and/or analyses, as well) and further prospecting for and/or producing hydrocarbons using the well.

It is intended that the foregoing detailed description be understood as an illustration of selected forms that the invention can take and not as a definition of the invention. It is only the following claims, including all equivalents which are intended to define the scope of the claimed invention. Further, it should be noted that any aspect of any of the preferred embodiments described herein may be used alone or in combination with one another. Finally, persons skilled in the art will readily recognize that in preferred implementation, some, or all of the steps in the disclosed method are performed using a computer so that the methodology is computer implemented. In such cases, the resulting physical properties model may be downloaded or saved to computer storage.

The following example embodiments of the invention are also disclosed in Embodiments 1 to 22 and Embodiments A1 to A20.

Embodiment 1. A computer-implemented method for integrating a full wavefield inversion (FWI) solution with a non-FWI solution, the method comprising: accessing the FWI solution, the FWI solution over a limited FWI bandwidth and comprising one or more FWI properties generated using FWI; accessing a non-FWI solution, the non-FWI solution over a non-FWI bandwidth that extends beyond the limited FWI bandwidth; combining the FWI solution with the non-FWI solution in order to generate a model estimate of at least a part of a subsurface, the model estimate extending beyond the limited FWI bandwidth; comparing the model estimate with one or more statistical or rock physics based models of the subsurface; modifying the model estimate, based on the comparison of the model estimate with one or more statistical models or rock physics based models of the subsurface, in order to generate an updated model estimate; iterating with the updated model estimate and the one or more statistical models or rock physics based models of the subsurface in order to further refine the updated model estimate; and using the updated model estimate for hydrocarbon management.

Embodiment 2. The method of Embodiment 1: wherein the FWI solution comprises any one or any combination of acoustic, elastic, anisotropic, viscous, and poro-elastic physics; and wherein the non-FWI solution comprises any one or any combination of rock physics based prior, statistically driven prior on rock properties, ray-based production, or wave-based imaged production such as offset and angle stacks.

Embodiment 3. The method of Embodiments 1 or 2: wherein the wave-based imaged production comprises offset and angle stacks.

Embodiment 4. The method of Embodiments 1 to 3: wherein the FWI solution comprises an elastic FWI solution; wherein the one or more FWI properties comprises one or more elastic FWI properties; wherein the FWI solution over the limited FWI bandwidth comprises the one or more elastic FWI properties generated from performing elastic FWI over the limited FWI bandwidth; wherein the non-FWI solution over the non-FWI bandwidth comprises a non-elastic FWI solution embodied over the non-FWI bandwidth; and wherein combining the FWI solution with the non-FWI solution in order to generate the model estimate of at least a part of the subsurface comprises combining the elastic FWI solution with the non-elastic FWI solution in order to generate the model estimate of at least a part of the subsurface.

Embodiment 5. The method of Embodiments 1 to 4: wherein the non-elastic FWI solution is based on one or both of seismic stacks or non-seismic data.

Embodiment 6. The method of Embodiments 1 to 5: wherein the non-elastic FWI solution is based on both of seismic stacks and non-seismic data.

Embodiment 7. The method of Embodiments 1 to 6: wherein the one or more statistical models of the subsurface comprises a rock physics statistical model indicative of one or more rock type classifiers.

Embodiment 8. The method of Embodiments 1 to 7: wherein combining the elastic FWI solution with the non-FWI solution in order to generate the model estimate comprises reverse filtering the elastic FWI properties in order to generate the model estimate.

Embodiment 9. The method of Embodiments 1 to 8: wherein comparing the model estimate with the one or more statistical models of the subsurface comprises generating rock-type labels and probabilities of one or more rock type classifications by classifying the model estimate using a rock physics statistical model.

Embodiment 10. The method of Embodiments 1 to 9: wherein modifying the model estimate comprises updating covariance between parameters of the model estimate and parameters of one or more prior models using the probabilities of the one or more rock type classifications.

Embodiment 11. The method of Embodiments 1 to 10: wherein iterating with the updated model estimate and the one or more statistical models of the subsurface in order to further refine the updated model estimate comprises reverse filtering input data and the one or more elastic FWI properties using the updated covariance and the one or more prior models.

Embodiment 12. The method of Embodiments 1 to 11: wherein iterating excludes modifying the one or more elastic FWI properties.

Embodiment 13. The method of Embodiments 1 to 12: wherein iterating comprises solving a maximum a posteriori problem, thereby integrating the elastic FWI solution with the non-elastic FWI solution while comporting with the probabilities of the one or more rock type classifications.

Embodiment 14. The method of Embodiments 1 to 13: combining the FWI solution with the non-FWI solution comprises solving a maximum a posteriori (MAP) problem.

Embodiment 15. The method of Embodiments 1 to 14: wherein the limited FWI bandwidth and the non-FWI bandwidth are at least partly overlapping.

Embodiment 16. The method of Embodiments 1 to 15: wherein at least a part of the limited FWI bandwidth does not overlap the non-FWI bandwidth.

Embodiment 17. The method of Embodiments 1 to 16: wherein the limited FWI bandwidth and the non-FWI bandwidth are mutually exclusive.

Embodiment 18. The method of Embodiments 1 to 17: wherein the limited FWI bandwidth covers a narrower frequency range than the non-FWI bandwidth.

Embodiment 19. The method of Embodiments 1 to 18: wherein the FWI bandwidth includes lower frequencies than the non-FWI bandwidth.

Embodiment 20. The method of Embodiments 1 to 19: wherein the updated model estimate is used for modifying a trajectory of a borehole for a well.

Embodiment 21: A system comprising: a processor: and a non-transitory machine-readable medium comprising instructions that, when executed by the processor, cause a computing system to perform a method according to any of Embodiments 1 to 20.

Embodiment 22: A non-transitory machine-readable medium comprising instructions that, when executed by a processor, cause a computing system to perform a method according to any of Embodiments 1 to 20.

Embodiment A1. A computer-implemented method for integrating a full wavefield inversion (FWI) solution with a non-FWI solution, the method comprising: accessing the FWI solution, the FWI solution over a limited FWI bandwidth and comprising one or more FWI properties generated using FWI; accessing a non-FWI solution, the non-FWI solution over a non-FWI bandwidth that extends beyond the limited FWI bandwidth; combining the FWI solution with the non-FWI solution in order to generate a model estimate of at least a part of a subsurface, the model estimate extending beyond the limited FWI bandwidth; comparing the model estimate with one or more statistical or rock physics based models of the subsurface; modifying the model estimate, based on the comparison of the model estimate with one or more statistical models or rock physics based models of the subsurface, in order to generate an updated model estimate; iterating with the updated model estimate and the one or more statistical models or rock physics based models of the subsurface in order to further refine the updated model estimate; and using the updated model estimate for hydrocarbon management.

Embodiment A2. The method of Embodiment A1, wherein the FWI solution comprises any one or any combination of acoustic, elastic, anisotropic, viscous, and poro-elastic physics; and wherein the non-FWI solution comprises any one or any combination of rock physics based prior, statistically driven prior on rock properties, ray-based production, or wave-based imaged production such as offset and angle stacks.

Embodiment A3. The method of Embodiment A2, wherein the wave-based imaged production comprises offset and angle stacks.

Embodiment A4. The method of Embodiment A1, wherein the FWI solution comprises an elastic FWI solution; wherein the one or more FWI properties comprises one or more elastic FWI properties; wherein the FWI solution over the limited FWI bandwidth comprises the one or more elastic FWI properties generated from performing elastic FWI over the limited FWI bandwidth; wherein the non-FWI solution over the non-FWI bandwidth comprises a non-elastic FWI solution embodied over the non-FWI bandwidth; and wherein combining the FWI solution with the non-FWI solution in order to generate the model estimate of at least a part of the subsurface comprises combining the elastic FWI solution with the non-elastic FWI solution in order to generate the model estimate of at least a part of the subsurface.

Embodiment A5. The method of Embodiment A4, wherein the non-elastic FWI solution is based on one or both of seismic stacks or non-seismic data.

Embodiment A6. The method of Embodiment A4, wherein the non-elastic FWI solution is based on both of seismic stacks and non-seismic data.

Embodiment A7. The method of Embodiment A4, wherein the one or more statistical models of the subsurface comprises a rock physics statistical model indicative of one or more rock type classifiers.

Embodiment A8. The method of Embodiment A7, wherein combining the elastic FWI solution with the non-FWI solution in order to generate the model estimate comprises reverse filtering the elastic FWI properties in order to generate the model estimate.

Embodiment A9. The method of Embodiment A8, wherein comparing the model estimate with the one or more statistical models of the subsurface comprises generating rock-type labels and probabilities of one or more rock type classifications by classifying the model estimate using a rock physics statistical model.

Embodiment A10. The method of Embodiment A9, wherein modifying the model estimate comprises updating covariance between parameters of the model estimate and parameters of one or more prior models using the probabilities of the one or more rock type classifications.

Embodiment A11. The method of Embodiment A10, wherein iterating with the updated model estimate and the one or more statistical models of the subsurface in order to further refine the updated model estimate comprises reverse filtering input data and the one or more elastic FWI properties using the updated covariance and the one or more prior models.

Embodiment A12. The method of Embodiment A11, wherein iterating excludes modifying the one or more elastic FWI properties.

Embodiment A13. The method of Embodiment A11, wherein iterating comprises solving a maximum a posteriori problem, thereby integrating the elastic FWI solution with the non-elastic FWI solution while comporting with the probabilities of the one or more rock type classifications.

Embodiment A14. The method of Embodiment A1, combining the FWI solution with the non-FWI solution comprises solving a maximum a posteriori (MAP) problem.

Embodiment A15. The method of Embodiment A1, wherein the limited FWI bandwidth and the non-FWI bandwidth are at least partly overlapping.

Embodiment A16. The method of Embodiment A15, wherein at least a part of the limited FWI bandwidth does not overlap the non-FWI bandwidth.

Embodiment A17. The method of Embodiment A1, wherein the limited FWI bandwidth and the non-FWI bandwidth are mutually exclusive.

Embodiment A18. The method of Embodiment A1, wherein the limited FWI bandwidth covers a narrower frequency range than the non-FWI bandwidth.

Embodiment A19. The method of Embodiment A1, wherein the FWI bandwidth includes lower frequencies than the non-FWI bandwidth.

Embodiment A20. The method of Embodiment A1, wherein the updated model estimate is used for modifying a trajectory of a borehole for a well.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions, and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements, and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A computer-implemented method for integrating a full wavefield inversion (FWI) solution with a non-FWI solution, the method comprising:
accessing the FWI solution, the FWI solution over a limited FWI bandwidth and comprising one or more FWI properties generated using FWI;
accessing a non-FWI solution, the non-FWI solution over a non-FWI bandwidth that extends beyond the limited FWI bandwidth;
combining the FWI solution with the non-FWI solution in order to generate a model estimate of at least a part of a subsurface, the model estimate extending beyond the limited FWI bandwidth;
comparing the model estimate with one or more statistical or rock physics based models of the subsurface;
modifying the model estimate, based on the comparison of the model estimate with one or more statistical models or rock physics based models of the subsurface, in order to generate an updated model estimate;
iterating with the updated model estimate and the one or more statistical models or rock physics based models of the subsurface in order to further refine the updated model estimate; and
using the updated model estimate for hydrocarbon management.

2. The method of claim 1, wherein the FWI solution comprises any one or any combination of acoustic, elastic, anisotropic, viscous, and poro-elastic physics; and
wherein the non-FWI solution comprises any one or any combination of rock physics based prior, statistically driven prior on rock properties, ray-based production, or wave-based imaged production such as offset and angle stacks.

3. The method of claim 2, wherein the wave-based imaged production comprises offset and angle stacks.

4. The method of claim 1, wherein the FWI solution comprises an elastic FWI solution;
wherein the one or more FWI properties comprises one or more elastic FWI properties;
wherein the FWI solution over the limited FWI bandwidth comprises the one or more elastic FWI properties generated from performing elastic FWI over the limited FWI bandwidth;
wherein the non-FWI solution over the non-FWI bandwidth comprises a non-elastic FWI solution embodied over the non-FWI bandwidth; and
wherein combining the FWI solution with the non-FWI solution in order to generate the model estimate of at least a part of the subsurface comprises combining the elastic FWI solution with the non-elastic FWI solution in order to generate the model estimate of at least a part of the subsurface.

5. The method of claim 4, wherein the non-elastic FWI solution is based on one of seismic stacks or non-seismic data.

6. The method of claim 4, wherein the non-elastic FWI solution is based on both of seismic stacks and non-seismic data.

7. The method of claim 4, wherein the one or more statistical models of the subsurface comprises a rock physics statistical model indicative of one or more rock type classifiers.

8. The method of claim 7, wherein combining the elastic FWI solution with the non-FWI solution in order to generate the model estimate comprises reverse filtering the elastic FWI properties in order to generate the model estimate.

9. The method of claim 8, wherein comparing the model estimate with the one or more statistical models of the subsurface comprises generating rock-type labels and probabilities of one or more rock type classifications by classifying the model estimate using a rock physics statistical model.

10. The method of claim 9, wherein modifying the model estimate comprises updating covariance between parameters of the model estimate and parameters of one or more prior models using the probabilities of the one or more rock type classifications.

11. The method of claim 10, wherein iterating with the updated model estimate and the one or more statistical models of the subsurface in order to further refine the updated model estimate comprises reverse filtering input data and the one or more elastic FWI properties using the updated covariance and the one or more prior models.

12. The method of claim 11, wherein iterating excludes modifying the one or more elastic FWI properties.

13. The method of claim 11, wherein iterating comprises solving a maximum a posteriori problem, thereby integrating the elastic FWI solution with the non-elastic FWI solution while comporting with the probabilities of the one or more rock type classifications.

14. The method of claim 1, wherein combining the FWI solution with the non-FWI solution comprises solving a maximum a posteriori (MAP) problem.

15. The method of claim 1, wherein the limited FWI bandwidth and the non-FWI bandwidth are at least partly overlapping.

16. The method of claim 15, wherein at least a part of the limited FWI bandwidth does not overlap the non-FWI bandwidth.

17. The method of claim 1, wherein the limited FWI bandwidth and the non-FWI bandwidth are mutually exclusive.

18. The method of claim 1, wherein the limited FWI bandwidth covers a narrower frequency range than the non-FWI bandwidth.

19. The method of claim 1, wherein the FWI bandwidth includes lower frequencies than the non-FWI bandwidth.

20. The method of claim 1, wherein the updated model estimate is used for modifying a trajectory of a borehole for a well.
